(19) United States
(12) Patent Application Publication
(10) Pub. No.: US 2013/0168520 A1
(43) Pub. Date: Jul. 4, 2013

(54) TESTING APPARATUS

(71) Applicants: HONG FU JIN PRECISION INDUSTRY (ShenZhen, Shenzhen City (CN); HON HAI PRECISION INDUSTRY CO., LTD., Tu-Cheng (TW)

(72) Inventor: FU-MING LIU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/626,992

(22) Filed: Sep. 26, 2012

(30) Foreign Application Priority Data
Dec. 28, 2011 (CN) 201110446824.8

(51) Int. Cl. H05K 7/14

(52) U.S. Cl. 248/327

(57) ABSTRACT

A testing apparatus includes a supporting device and a mounting device. The mounting device includes a clamping member. The clamping member includes a first clamping post, a second clamping post, and a screw post located between the first clamping post and the second clamping post. The first clamping post includes a clamping portion for positioning an electronic device. The screw post is moveable relative to the first clamping post and the second clamping post in a direction that is substantially perpendicular to a plane of the supporting device located, so that a distance between the clamping portion and the supporting device is adjusted.

### BACKGROUND

1. Technical Field

The present disclosure relates to testing apparatuses, more particularly to a testing apparatus for an electronic device.

2. Description of Related Art

An electronic device, such as a computer, often needs various tests, such as a vibration test or an impact test. When testing, the electronic device is secured to a clamping device, and the clamping device is placed on a testing platform. Generally, the clamping device includes a securing post secured to the testing platform and a pressing post secured to the securing post. The electronic device is located between the securing post and the pressing post during the test. The pressing post is often secured to the securing post by a plurality of screws, and using screws is laborious and time-consuming. Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a testing apparatus in accordance with an embodiment.

FIG. 2 is an assembled view of the testing apparatus of FIG. 1, and a first electronic device is secured to the testing apparatus.

FIG. 3 is an assembled view of the testing apparatus and a second electronic device in accordance with an embodiment.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

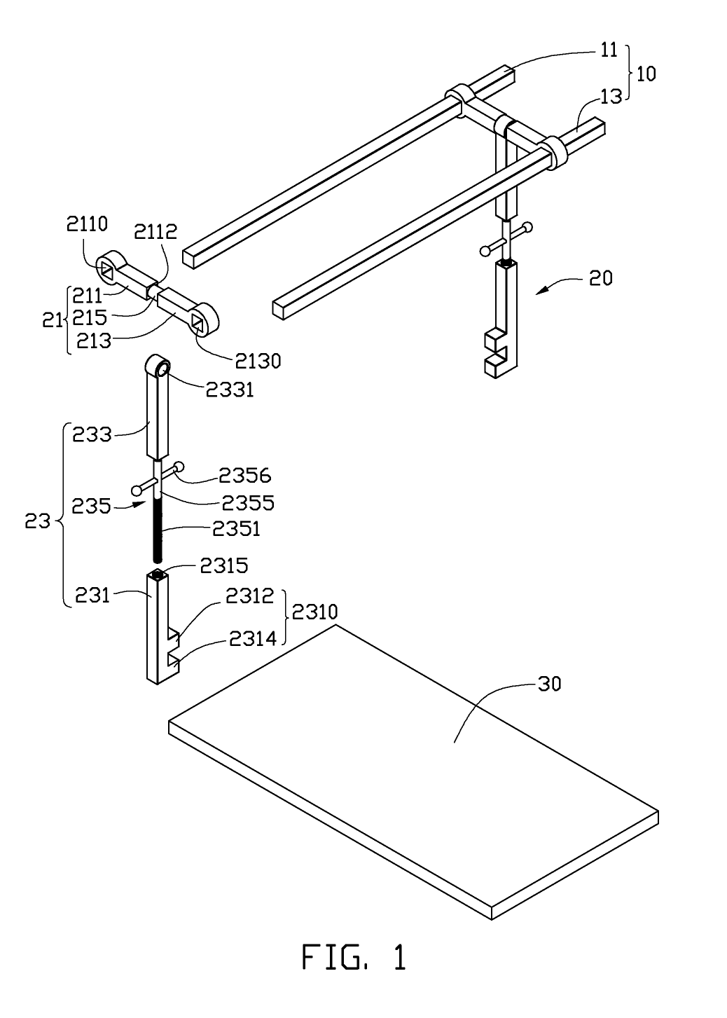

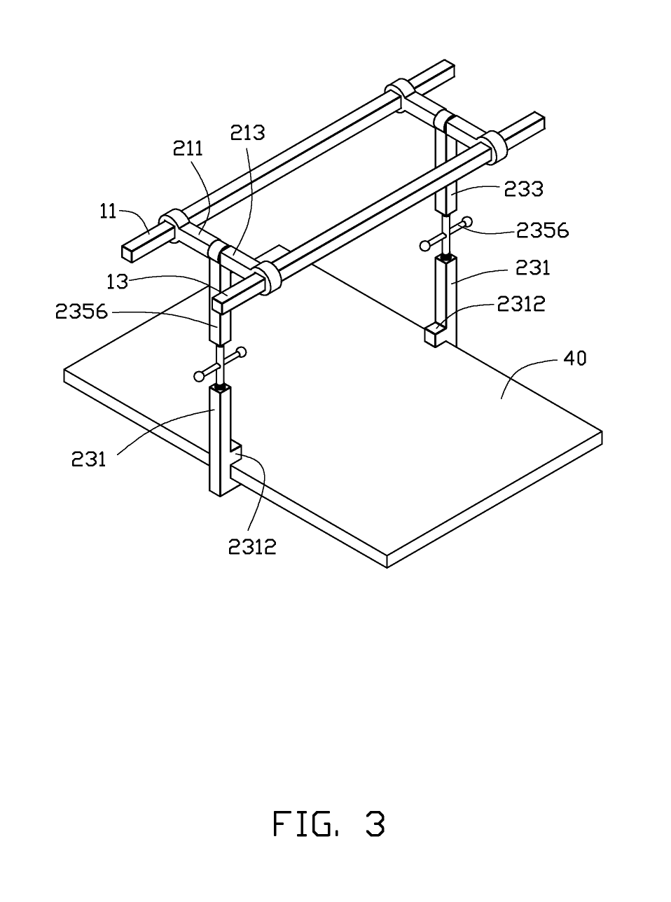

FIG. 1 illustrates a testing apparatus in accordance with an embodiment for testing a first electronic device 30 and a second electronic device 40 (see FIG. 3). The testing apparatus comprises a supporting device 10 and two mounting devices 20 attached to the supporting device 10. In one embodiment, a width of the first electronic device 30 is greater than a width of the second electronic device 40.

The supporting device 10 comprises a first supporting post 11 and a second supporting post 13. In one embodiment, the first supporting post 11 is substantially parallel to the second supporting post 13, and a cross-section of the first supporting post 11 is substantially a rectangle. The second supporting post 13 has a same configuration as the first supporting post 11.

Each of the two mounting devices 20 comprises a mounting member 21 and a clamping member 23 attached to the mounting member 21. The mounting member 21 comprises a first mounting post 211, a second mounting post 213, and a connecting post 215 connected to the first mounting post 211 and the second mounting post 213. The first mounting post 211 defines a first receiving hole 2110 and a first retaining hole 2112. The second mounting post 213 defines a second receiving hole 2130 and a second retaining hole (not shown). The opposite ends of the connecting post 215 are engaged in the first retaining hole 2112 and the second retaining hole, respectively.

The clamping member 23 comprises a first clamping post 231, a second clamping post 233, and a screw post 235 located between the first clamping post 231 and the second clamping post 233. A clamping potion 2310 extends from the bottom of the first clamping post 231, and a first screw hole 2315 is defined in the first clamping post 231.

The clamping portion 2310 comprises a first clamping panel 2312 and a second clamping panel 2314 under the first clamping panel 2312. In one embodiment, the first clamping panel 2312 is substantially parallel to the second clamping panel 2314 and perpendicular to the first clamping post 231. The second clamping post 233 defines a securing hole 2331 and a second screw hole (not shown).

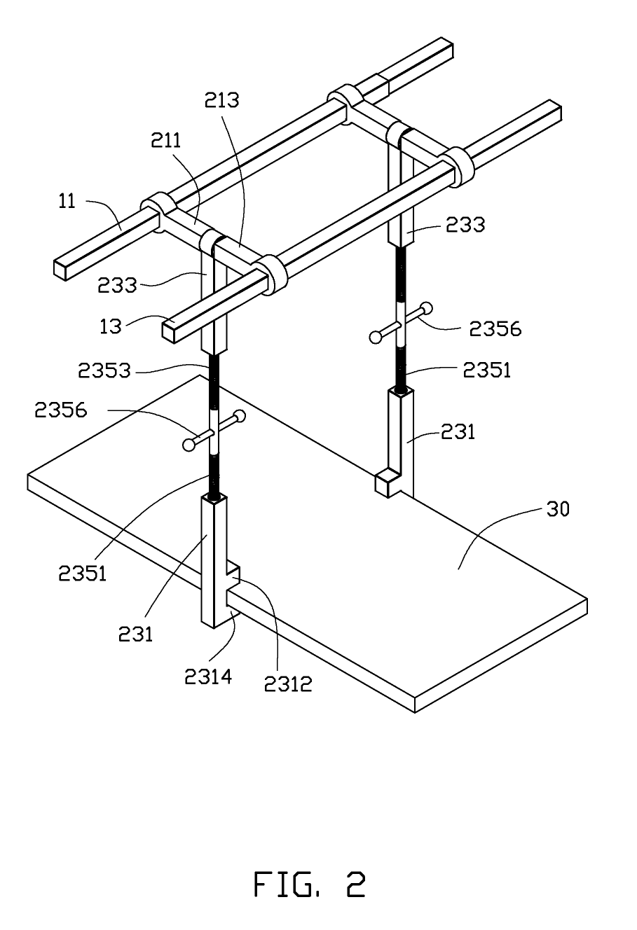

The screw post 235 comprises a first screw portion 2351, a second screw portion 2353 (see FIG. 2), and a connecting portion 2355 connected to the first screw portion 2351 and the second screw portion 2353. The first screw portion 2351 is engaged with the first screw hole 2315, and the second screw portion 2353 is engaged with the second screw hole. Two operating portions 2356 extend from opposite sides of the connecting portion 2355. In one embodiment, a length of the first screw portion 2351 is substantially equal to a length of the second screw portion 2353, and the operating portions 2356 are substantially perpendicular to the connecting portion 2355.

FIG. 2 illustrates a first assembled view of the testing apparatus in accordance with an embodiment. In assembly, the connecting post 215 is disengaged from the first retaining hole 2112. The connecting post 215 extends through the securing hole 2331 and is engaged in the first retaining hole 2112, securing the second clamping post 233 to the connecting post 215. The first supporting post 11 is extended through the first receiving hole 2110, and the second supporting post 13 is extended through the second receiving hole 2130, securing the mounting member 21 to the supporting device 10.

The first electronic device 30 is positioned between the two mounting devices 20, and the opposite ends of the first electronic device 30 is sandwiched between the first clamping panel 2312 and the second clamping panel 2314. The two mounting devices 20 move towards the first electronic device 30 in a direction substantially parallel to a plane of the supporting device 10, until a distance between the two mounting devices 20 is substantially equal to a width of the first electronic device 30. Thus, the first electronic device 30 can be secured between the two mounting devices 20.

FIG. 3 illustrates a second assembled view of the testing apparatus in accordance with an embodiment. When the second electronic device 40 needs to be secured to the testing apparatus, the two mounting devices 20 are moved towards the second electronic device 40 in a direction substantially parallel to the plane of the supporting device 10. Otherwise, one of the two mounting devices 20 is moved towards the second electronic device 40 in a direction substantially parallel to the plane of the supporting device 10, until a distance between the two mounting devices 20 is substantially equal to a width of the second electronic device 40.

When a distance between the supporting device 10 and the first electronic device 30 needs to be adjusted, or the distance between the supporting device 10 and second electronic device 40 needs to be adjusted, the operating portions 2356 are operated to rotate the screw post 235. The first screw portion 2351 is moved upward or downward along the first clamping post 231 and out of the first clamping post 231 in a direction substantially perpendicular to the plane of the supporting device 10. Simultaneously, the second screw portion 2353 is moved downward or upward along the second clamping post 233 and out of the second clamping post 233 in a direction substantially perpendicular to the plane of the supporting device 10. A distance between the first clamping post 231 and the second clamping post 233 is adjusted. Thus, the distance between the supporting device 10 and the first electronic device 30 can be adjusted, or the distance between the supporting device 10 and second electronic device 40 can be adjusted. In one embodiment, the first screw portion 2351 moved along the first clamping post 231 an opposite direction from the second screw portion 2353 moved along the second clamping post 233. That is, when the first screw portion 2351 is moved upward along the first clamping post 231, the second screw portion 2353 is moved downward along the second clamping post 233. Otherwise, when the first screw portion 2351 is moved upward along the first clamping post 231, the second screw portion 2353 is moved downward along the second clamping post 233.

In disassembly of the first electronic device 30 or the second electronic device 40, the two mounting devices 20 are moved away from the first electronic device 30 or second electronic device 40 in a direction substantially parallel to the plane of the supporting device 10 located. Otherwise, one of the two mounting devices 20 is moved away from the first electronic device 30 or the second electronic device 40 in a direction substantially parallel to the plane of the supporting device 10. Until the two mounting devices 20, or the one of the two mounting devices 20 is disengaged from the first electronic device 30 or the second electronic device 40. Then the first electronic device 30 or the second electronic device 40 can be disengaged from the testing apparatus.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A testing apparatus comprising:
a supporting device defining a plane; and
a mounting device attached to the supporting device; the mounting device comprises a clamping member; the clamping member comprises a first clamping post, a second clamping post, and a screw post connecting the first clamping post and the second clamping post; the first clamping post comprises a clamping portion configured to position an electronic device,
wherein the screw post is moveable relative to the first clamping post and the second clamping post in a direction substantially perpendicular to the plane of the supporting device, a distance between the clamping portion and the supporting device is adjustable by moving the screw post in the direction.

2. The testing apparatus of claim 1, wherein the clamping portion extends from a bottom of the first clamping post.

3. The testing apparatus of claim 1, wherein the mounting device further comprises a mounting member attached to the second clamping post, the mounting member is moveably attached to the supporting device.

4. The testing apparatus of claim 3, wherein the mounting member is moveable in a direction substantially parallel to the plane of the supporting device.

5. The testing apparatus of claim 3, wherein the supporting device comprises a first supporting post and a second supporting post, and the second supporting post is substantially parallel to the first supporting post and perpendicular to the mounting member.

6. The testing apparatus of claim 5, wherein the mounting member comprises a first mounting post attached to the first supporting post and a second mounting post attached to the second supporting post, and the second clamping post is located between the first mounting post and the second mounting post.

7. The testing apparatus of claim 1, wherein the screw post comprises a first screw portion and a second screw portion, the first screw portion is moveably engaged with the first clamping post, and the second screw portion is moveably engaged with the second clamping post.

8. The testing apparatus of claim 7, wherein the first clamping post defines a first screw hole for receiving the first screw portion, and the second clamping post defines a second screw hole for receiving the second screw portion.

9. The testing apparatus of claim 7, wherein a length of the first screw portion is substantially equal to a length of the second screw portion.

10. The testing apparatus of claim 1, wherein the clamping portion comprises a first clamping panel and a second clamping panel substantially parallel to the first clamping panel, and the first clamping panel and the second clamping panel are configured for sandwiching the electronic device therebetween.

11. A testing apparatus comprising:
a supporting device defining a plane;
a mounting device attached to the supporting device; the mounting device comprises
a mounting member attached to the supporting device and clamping member attached to the mounting member; the clamping member comprises a first clamping post, a second clamping post, and a screw post connecting the first clamping post and the second clamping post; the first clamping post comprises a clamping portion configured to position an electronic device;
wherein the mounting member is moveable relative to the supporting device in a direction substantially parallel to the plane of the supporting device; the screw post is moveable relative to the first clamping post and the second clamping post in a direction substantially perpendicular to the plane of the supporting device, a distance between the clamping portion and the supporting device is adjustable by moving the screw post relative to the first clamping post or to the second clamping post.

12. The testing apparatus of claim 11, wherein the clamping portion extends from a bottom of the first clamping post.

13. The testing apparatus of claim 11, wherein the clamping portion comprises a first clamping panel and a second clamping panel substantially parallel to the first clamping panel, and the first clamping panel and the second clamping panel are configured for sandwiching the electronic device therebetween.

14. The testing apparatus of claim 11, wherein the supporting device comprises a first supporting post and a second supporting post, and the second supporting post is substantially parallel to the first supporting post and perpendicular to the mounting member.

15. The testing apparatus of claim 14, wherein the mounting member comprises a first mounting post attached to the first supporting post and a second mounting post attached to the second supporting post, and the second clamping post is located between the first mounting post and the second mounting post.

16. The testing apparatus of claim 11, wherein the screw post comprises a first screw portion and a second screw portion, the first screw portion is moveably engaged with the first clamping post, and the second screw portion is moveably engaged with the second clamping post.

17. The testing apparatus of claim 16, wherein the first clamping post defines a first screw hole for receiving the first screw portion, and the second clamping post defines a second screw hole for receiving the second screw portion.

18. The testing apparatus of claim 16, wherein a length of the first screw portion is substantially equal to a length of the second screw portion.

19. The testing apparatus of claim 16, wherein the screw post further comprises a connecting portion connected between the first screw portion and the second screw portion, and two operating portions extend from opposite sides of the connecting portion.

20. The testing apparatus of claim 19, wherein the two operating portions are substantially perpendicular to the connecting portion.
